(19) United States
(12) Patent Application Publication
(10) Pub. No.: US 2014/0360041 A1
(43) Pub. Date: Dec. 11, 2014

(54) SUBSTRATE TREATING APPARATUS

(71) Applicant: Samsung Electronics Co., Ltd., Suwon-si (KR)

(72) Inventors: Jihoon JEONG, Guri-si (KR); Yongsun KO, Suwon-si (KR); Kuntack LEE, Suwon-si (KR); Kyoungseob KIM, Suwon-si (KR); SeokHoon KIM, Seongnam-si (KR); Jung-Min OH, Incheon (KR); Yongmyung JUN, Hwaseong-si (KR); Yong-Jhin CHO, Hwaseong-si (KR)

(73) Assignee: SAMSUNG ELECTRONICS CO., LTD., Suwon-si (KR)

(21) Appl. No.: 14/246,274

(22) Filed: Apr. 7, 2014

(30) Foreign Application Priority Data
Jun. 11, 2013 (KR) 10-2013-0066681

(51) Int. Cl. H01L 21/02; F26B 25/06

(52) U.S. Cl. CPC H01L 21/02101; F26B 25/06
USPC 34/218

(57) ABSTRACT

A substrate treating apparatus includes a fluid supply unit to supply a fluid to a chamber. The substrate is dried in the chamber using the fluid in a supercritical state. The fluid supply unit includes a storing tank to store the fluid and a conversion tank connected to the storing tank through a connection tube and to the chamber through a supply tube. The conversion tank includes a heater to heat the fluid.

### CROSS-REFERENCE TO RELATED APPLICATION

Korean Patent Application No. 10-2013-0066681, filed on Jun. 11, 2013, and entitled, “Substrate Treating Apparatus,” is incorporated by reference herein in its entirety.

### BACKGROUND

1. Field

One or more embodiments described herein to a treating substrates.

2. Description of the Related Art

Semiconductor devices are manufactured using various processes. One process is a photolithography process, in which a circuit pattern is formed on a substrate such as a silicon wafer. During manufacture, various foreign substances such as particles, organic contaminants, metal impurities, and the like, may be generated. The foreign substances cause defects which degrade performance and yield of the semiconductor devices. Thus, cleaning processes may be performed in an attempt to remove the foreign substances.

The cleaning processes include a chemical process for removing foreign substances on a substrate, a washing process for washing away the chemicals using deionized (DI) water, and a drying process for drying the substrate. A typical drying process involves replacing DI water on the substrate with an organic solvent, such as isopropyl alcohol (IPA) having a relatively low surface tension. When the IPA evaporates, the substrate is dried.

The drying process has a number of drawbacks. For example, the drying process may cause pattern collapse in the semiconductor device. This collapse may be pronounced in semiconductor devices having fine circuit patterns of line widths of about 30 nm or less. This collapse may occur even though an organic solvent is used for drying.

### SUMMARY

In accordance with one embodiment, a substrate treating apparatus includes a chamber to dry a substrate using a fluid in a supercritical state and a process fluid supply unit to supply the fluid to the chamber, wherein the process fluid supply unit includes a storing tank to store the fluid and a conversion tank connected to the storing tank through a connection tube and connected to the chamber through a supply tube, the conversion tank including a heater to heat the fluid.

The heater may include a body coupled to an inner wall of a housing of the conversion tank and at least one heat exchange member coupled to an outer surface of the body. The at least one heat exchange member may have a plate shape and may be disposed to cross a longitudinal direction of the body. A plurality of heat exchange members may be arranged to be spaced apart from each other along the longitudinal direction of the body. The at least one exchange member may have a hole.

The at least one heat exchange member may have a plate shape, and the at least one heat exchange member may be on the body and may be substantially parallel to a longitudinal direction of the body. The at least one heat exchange member may be spirally disposed on the outer surface of the body.

The conversion tank may include a housing including the inner space and the connection tube and the supply tube may be connected to the housing and face each other. The heater may extend in a longitudinal direction and the connection tube extends in the longitudinal direction and faces the supply tube.

The conversion tank may include a first conversion tank and a second conversion tank substantially parallel to the first conversion tank and connected to the connection tube. The supply tube may be connected to the first conversion tank, and the second conversion tank may be connected to the first conversion tank through a supplement tube to supply the fluid into the first conversion tank.

The first conversion tank may be connected to the chamber through a first supply tube, and the second conversion tank may be connected to the chamber through a second supply tube. The first conversion tank may be connected to the chamber through a first supply tube, the second conversion tank may be connected to the chamber through a second supply tube, and the first and second conversion tanks may be connected to each other through a supplement tube.

One of the first or second conversion tank may function as a main conversion tank to supply the fluid into the chamber, and the other of the first or second conversion tank may function as a sub-conversion tank to supply the fluid into the main conversion tank. The first or second conversion tank may selectively supply the fluid into the chamber.

In accordance with another embodiment, a substrate treating apparatus may include a surface to support a substrate and a chamber to dry the substrate using a fluid in a supercritical state, wherein the surface is included in the chamber. The apparatus may include a supply source to supply the fluid to the chamber, wherein the supply source may include a first tank to store the fluid and a second tank to receive the fluid from the first tank and wherein the second tank includes a heater to heat the fluid.

The fluid may be heated and pressurized in at least one of the first tank or the second tank. The apparatus may include a circulator to recycle the fluid in the chamber after the substrate is dried. The fluid in the supercritical state may include carbon dioxide.

### BRIEF DESCRIPTION OF THE DRAWINGS

Features will become apparent to those of ordinary skill in the art by describing in detail exemplary embodiments with reference to the attached drawings in which:

FIG. 1 illustrates an embodiment of a substrate treating apparatus;

FIG. 2 illustrates a cross-sectional view of a first process chamber in FIG. 1;

FIG. 3 illustrates a graph of a phase change of carbon dioxide;

FIG. 4 illustrates a tube of a second process chamber of FIG. 1;

FIG. 5 illustrates a process fluid supply unit of FIG. 4;

FIG. 6 illustrates a conversion tank of FIG. 5;

FIG. 7 illustrates a cross-sectional view of the conversion tank of FIG. 6;

FIG. 8 illustrates a heater according to one embodiment;

FIGS. 9 and 10 illustrates a heater according to another embodiment;

FIG. 11 illustrates an embodiment of a process fluid supply unit;

FIG. 12 illustrates control of the process fluid supply unit;

FIG. 13 illustrates another embodiment of a process fluid supply unit;

FIG. 14 illustrates control of the process fluid supply unit of FIG. 13;

FIG. 15 illustrates another embodiment of a process fluid supply unit; and

FIG. 16 illustrates control of the process fluid supply unit of FIG. 15.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

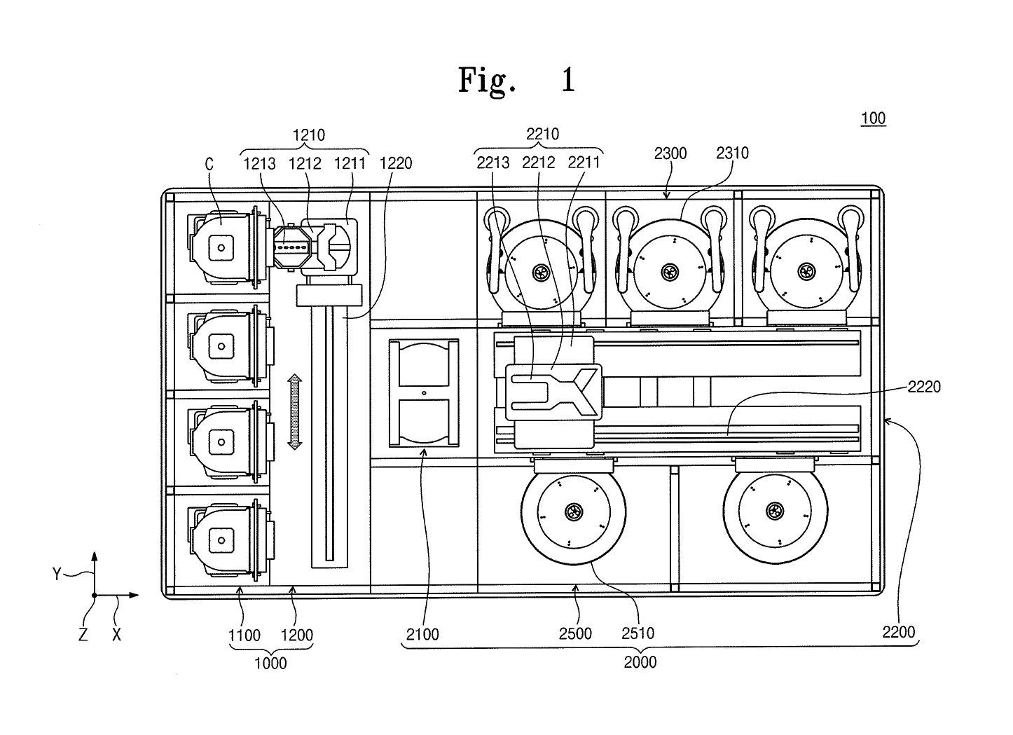

FIG. 1 illustrates an embodiment of a substrate treating apparatus 100 which includes an index module 1000 and a process module 2000. The index module 1000 may be an equipment front end module (EFEM) and may include a load port 1100 and a transfer frame 1200. The index module 1000 receives a substrate S from an external location to provide the substrate S to the process module 2000.

The load port 1100, transfer frame 1200, and process module 2000 may be successively arranged in a line. A direction in which the load port 1100, transfer frame 1200, and process module 2000 are arranged may be referred to as a first direction X. Also, when viewed from an upper side, a direction perpendicular to the first direction may be referred to as a second direction Y. A direction perpendicular to the first and second directions X and Y may be referred to as a third direction Z.

At least one load port 1100 may be provided in the index module 1000. The load port 1100 is disposed on a side of the transfer frame 1200. If a plurality of load ports 1100 are provided, the load ports 1100 may be arranged in line in second direction Y.

The number and arrangement of load ports 1100 may be different in other embodiments. For example, the number and arrangement of load ports 1100 may be based on a foot print of the substrate treating apparatus, may be different according to process efficiency, and/or may different based on a relative arrangement of one or more other substrate treating apparatuses.

A carrier C which includes substrate S is disposed in the load port 1100. The carrier C may be carried from an external location, and then loaded into the load port 1100 or unloaded from the load port 1100 and carried to the external or another location. In one embodiment, the carrier C may be carried between the substrate treating apparatuses 100 by a conveyor such as an overhead hoist transfer (OHT). Also, substrate S may be carried by one or more other transfer units such as an automatic guided vehicle, a rail guided vehicle, or even a worker.

As previously indicated, substrate S is accommodated in carrier C. A front opening unified pod (FOUP) may be used as the carrier C. At least one slot supporting an edge of the substrate S may be defined inside the carrier C. If a plurality of slots is provided, the slots may be spaced apart from each other along the third direction Z. Thus, the substrate S may be disposed within the carrier C. According to one example, twenty-five substrates S may be accommodated in the carrier C. The carrier C may have an interior area isolated and sealed from the outside by a door which opens and closes. As a result, the substrate S inside may be prevented from being contaminated when located in carrier C.

The transfer frame 1200 includes an index robot 1210 and an index rail 1220. The transfer frame 1200 carries the substrate S between the carrier C located in the load port 1100 and the process module 2000. The index rail 1220 provides a moving path for the index robot 1210. The index rail 1220 may extend in a longitudinal direction parallel to the second direction Y.

The index robot 1210 carries the substrate S. The index robot 1210 may include a base 1211, a body 1212, and an arm 1213. The base 1211 is disposed on and moves along the index rail 1220. The body 1212 is coupled to the base 1211. The body 1212 may move in the third direction Z on the base 1211 and/or may rotate using the third direction Z as an axis.

The arm 1213 is disposed on the body 1212 and may move forwards and backwards. The arm 1213 may have a hand on one end to pick up or down the substrate S. In one embodiment, the index robot 1210 may have a plurality of arms 1213. If the index robot 1210 has a plurality of arms 1213, the arms 1213 may be stacked on body 1212 in the third direction Z. Each of the arms 1213 may be operated independently.

In the index robot 1210, the base 1211 may move in the second direction Y on the index rail 1220. The index robot 1210 may take substrate S out of the carrier C and transfer the substrate S into process module 2000. The index robot 1210 may also take substrate S out of the process module 2000 and place the substrate S into the carrier C, according to operations of the body 1212 and the arm 1213.

In an alternative embodiment, the index rail 1220 may be omitted in the transfer frame 1200 and the index robot 1210 may be fixed to the transfer frame 1200. In this case, the index robot 1210 may be disposed at a central portion of the transfer frame 1200.

The process module 2000 includes a buffer chamber 2100, a transfer chamber 2200, a first process chamber 2300, and a second process chamber 2500. The process module 2000 receives the substrate S from the index module 1000 to perform a cleaning process on the substrate S. The buffer chamber 2100 and the transfer chamber 2200 are disposed in the first direction X. The transfer chamber 2200 extends in a longitudinal direction parallel to the first direction X.

The process chambers 2300 and 2500 may be disposed on side surfaces of the transfer chamber 2200 in the second direction Y, respectively. In one embodiment, the first process chamber 2300 may be disposed on one side of the transfer chamber 2200 in the second direction Y, and the second process chamber 2500 may be disposed on an opposing side of the transfer chamber 2200. Only one first process chamber 2300 may be provided or a plurality of first process chambers 2300 may be provided. If a plurality of first process chambers 2300 are provided, the first process chambers 2300 may be disposed on one side of the transfer chamber 2200 in the first direction X, stacked along the third direction Z, or disposed in combination thereof.

Only one second process chamber 2500 may be provided or a plurality of second process chambers 2500 may be provided. If a plurality of second process chambers 2500 are provided, the second process chambers 2500 may be disposed in the first direction X on the other side of the transfer chamber 2200, stacked along the third direction Z, or disposed in combination thereof.

In other embodiments, chambers 2100, 2200, 2300, and 2500 in the process module 2000 may be arranged in a different manner. For example, chambers 2100, 2200, 2300, and 2500 may be disposed in an arrangement which achieves a certain (e.g., optimal) level of process efficiency. According to one such arrangement, the first and second process chambers 2300 and 2500 may be disposed on a same surface as the transfer chamber in the first direction X or may be stacked on each other.

The buffer chamber 2100 is disposed between the transfer frame 1200 and the transfer chamber 2200. The buffer chamber 2100 provides a buffer space in which the substrate S, carried between the index module 1000 and the process module 2000, temporarily stays. At least one buffer slot in which the substrate S is placed may be provided within the buffer chamber 2100. When a plurality of buffer slots is provided, the buffer slots may be spaced apart from each other along the third direction Z.

The substrate S taken out of the carrier C by the index robot 1210 may be located in the buffer slot. Alternatively, the substrate C carried from the process chambers 2300 and 2500 by the transfer robot 2210 of the transfer chamber 2200 may be located in the buffer slot. Also, the index robot 1210 or the transfer robot 2210 may take the substrate S out of the buffer slot in order to allow the substrate S to be placed into the carrier C, or may carry the substrate S into process chambers 2300 and 2500.

The transfer chamber 2200 carries the substrate S among the chambers 2100, 2300, and 2500, which may be disposed around the transfer chamber 2200. For example, the buffer chamber 2100 may be disposed on one side of the transfer chamber 2200 in the first direction X. The process chambers 2300 and 2500 may be disposed on one side or both sides of the transfer chamber 2200 in the second direction Y. The transfer chamber 2200 may carry the substrate S among the buffer chamber 2100, the first process chamber 2300, and the second process chamber 2500. The transfer chamber 2200 may include transfer rails 2220 and a transfer robot 2210.

The transfer rails 2220 provide a moving path of the transfer robot 2210 which carries the substrate S. The transfer rails 2220 may be disposed parallel to each other in the first direction X. The transfer robot 2210 may include a base 2211, a body 2212, and an arm 2213. The respective components of the transfer robot 2210 may be similar to index robot 1210. The transfer robot 2210 carries the substrate S among the buffer chamber 2100, first process chamber 2300, and second process chamber 2500 by the operations of the body 2212 and the arm 2213, while the base 2211 moves along the transfer rail 2220.

The first and second process chambers 2300 and 2500 may perform processes on substrate S that are different from each other. Also, in one embodiment, a first process performed in the first process chamber 2300 and a second process performed in the second process chamber 2500 may be successively performed. For example, a chemical process, a cleaning process, and a first drying process may be performed in the first process chamber 2300. Then, a second drying process may be performed in the second process chamber 2500. The first drying process may be a wet drying process performed using an organic solvent, and the second drying process may be a supercritical drying process performed using a supercritical process fluid. In one embodiment, one of the first or second drying processes may be selectively performed.

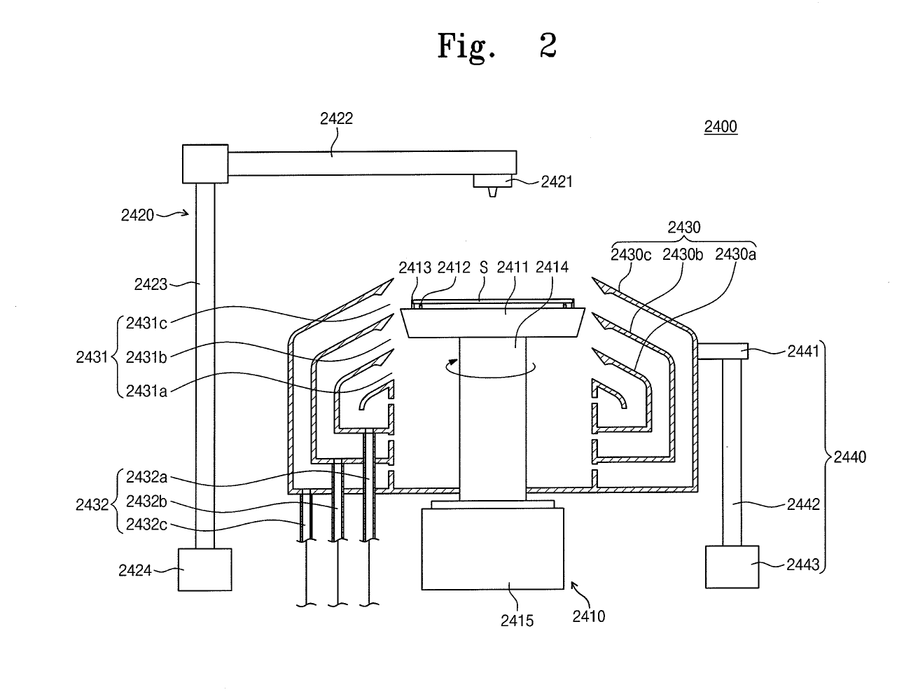

FIG. 2 illustrates a cross-sectional view of a first process chamber shown in FIG. 1. Referring to FIGS. 1 and 2, the first process chamber 2300 includes a housing 2310 and a process unit 2400. The first process is performed in the first process chamber 2300. The first process may include at least one of the chemical process, the cleaning process, or the first drying process. The first drying process may be omitted in an alternative embodiment.

The housing 2310 defines an outer wall of the first process chamber 230. The process unit 2400 is disposed within the housing 2310 to perform the first process. The process unit 2400 includes a spin head 2410, a fluid supply member 2420, a recovery container 2430, and an elevation member 2440. A substrate S is seated on spin head 2410, and spin head 2410 rotates the substrate S while the process is performed.

The spin head 2410 may include a support plate 2411, support pins 2412, chucking pins 2413, a rotation shaft 2414, and a motor 2415. The support plate 2411 includes an upper portion which may have a shape substantially similar to substrate S. For example, the upper portion of support plate 2411 may have a circular shape.

The plurality of support pins 2412 on which the substrate S is placed and the plurality of chucking pins 2413 for fixing the substrate S are disposed on the support plate 2411. The rotation shaft 2414 rotated by the motor 2415 is fixed and coupled to a bottom surface of the support plate 2411. The motor 2415 generates a rotational force using external power to rotate the substrate plate 2411 through the rotational shaft 2414. Thus, the substrate S may be seated on the spin head 2410, and the support plate 2411 may be rotated to rotate the substrate S while the first process is performed.

Each of the support pins 2412 protrudes from a top surface of the support plate 2411 in the third direction Z. The support pins 2412 are disposed to be spaced a preset distance from each other. When viewed from an upper side, the support pins 2412 may be arranged in a generally circular ring shape. A back surface of the substrate S may be placed on the support pins 2412. Thus, the substrate S may be seated on support pins 2412 and spaced a distance, which corresponds to a protruding distance of the support pins 2412, relative to a top surface of the support plate 2411.

Each of the chucking pins 2413 may protrude from the top surface of the support plate 2411 in the third direction Z. The chucking pins 2413 may be disposed further away from a center of the support plate 2411 than the support pins 2412. The chucking pins 2413 may be moved between a fixed position and a pick-up position along a radius direction of the support plate 2411. The fixed position may represent a position that is spaced a distance corresponding to a radius of the substrate S from the center of the support plate 2411. The pick-up position may represent a position that is further away from the center of the support plate 2411 than the fixed position.

The chucking pins 2413 are disposed at the pick-up position when the substrate S is loaded on the spin head 241 by the transfer robot 2210. When the substrate S is loaded and the process is to be performed, the chucking pins 2413 may be moved to the fixed position to contact a side surface of the substrate S, to thereby fix the substrate S in position. When the process is finished, the transfer robot 2210 picks up the substrate S to unload the substrate S. The chucking pins 2413 may then be moved again to the pick-up position. Thus, the chucking pins 2413 may prevent the substrate S from being separated from the home position by a rotational force when spin head 2410 is rotated.

The fluid supply member 2420 may include a nozzle 2421, a support 2422, a support shaft 2423, and a driver 2424. The fluid supply member 2420 supplies a fluid onto the substrate S. The support shaft 2423 extends in a longitudinal direction parallel to the third direction 16. The driver 2424 is coupled to a lower end of the support shaft 2423. The driver 2424 rotates the support shaft 2423 or vertically moves the support shaft 2423 along the third direction Z. The support 2422 is perpendicularly coupled to an upper portion of the support shaft 2423.

The nozzle 2421 is disposed on a bottom surface of an end of the support 2422. The nozzle 2421 may be moved between a process position and a standby position by the rotation and elevation of the support shaft 2423 through the driver 2424. The process position may correspond to a position at which the nozzle 2421 is disposed directly above the support plate 2411. The standby position may correspond to a position at which the nozzle 2421 which deviates or is offset from the direct upper side of the support plate 2411.

At least one fluid supply member 2420 may be provided in the process unit 2400. For example, the fluid supply member 2420 may supply a detergent, a rinsing agent, and/or an organic solvent. Examples of the detergent include hydrogen (H₂O₂) solution, a solution in which ammonia (NH₄OH), hydrochloric acid (HCl), sulfuric acid (H₂SO₄) is mixed with the hydrogen (H₂O₂) solution, or a hydrofluoric acid solution. An example of the rinsing agent may be deionized (DI) water. Examples of the organic solvent include isopropyl alcohol, isopropyl alcohol, ethyl glycol, 1-propanol, tetra hydraulic franc, 4-hydroxyl, 4-methyl, 2-pentanone, 1-butanol, 2-butanol, methanol, ethanol, n-propyl alcohol, or dimethylether.

In one embodiment, a plurality of fluid supply members 2420 are provided. The fluid supply members 2420 may supply fluids that are different from each other. For example, each fluid supply member 2420 may respectively supply a detergent, a rinsing agent, or an organic solvent. In one application, a first fluid supply member 2420a may spray the ammonia hydrogen peroxide solution, a second fluid supply member 2420b may spray the deionized water, and a third fluid supply member 2420c may spray the isopropyl alcohol solution.

When the substrate S is seated on the spin head 2410, the fluid supply member 2420 may move from the standby position to the process position to supply the above-described fluid(s) onto the substrate S. For example, the fluid supply member(s) may supply the detergent, the rinsing agent, and the organic solvent to perform the chemical process, the cleaning process, and the first drying process, respectively. The spin head 2410 may be rotated by the motor 2415 to uniformly supply the fluids onto a top surface of the substrate S while the process(es) are performed.

The recovery container 2430 provides a space in which the first process is performed. Also, the recovery container 2430 recovers the fluids used for the first process. When viewed from an upper side, the recovery container 2430 is disposed around the spin head 2410 to surround the spin head 2410 and has an opened upper side. At least one recovery container 2430 may be provided in the process unit 2400. Hereinafter, an example where the process unit 2400 includes three recovery containers 2430 (i.e., first recovery container 2430a, second recovery container 2430b, and third recovery container 2430c) is discussed. The number of recovery containers 2430 may be differently selected based on the number of fluids and conditions of the first process.

Each of the first recovery container 2430a, the second recovery container 2430b, and the third recovery container 2430c may have a circular ring shape surrounding the spin head 2410. The first recovery container 2430a, the second recovery container 2430b, and the third recovery container 2430c may be successively disposed away from a center of the spin head 2410. That is, the first recovery container 2430a surrounds the spin head 2410, the second recovery container 2430b surrounds the first recovery container 2430a, and the third recovery container 2430c surrounds the second recovery container 2430b.

The first recovery container 2430a has a first inflow hole 2431a defined by an inner space thereof. The second recovery container 2430b has a second inflow hole 2431b defined by a space between the first and second recovery containers 2430a and 2430b. The third recovery container 2430c has a third inflow hole 2431c defined by a space between the second recovery container 2430b and third recovery container 2430c.

At least one recovery line 2432 extends downward in the third direction Z and is connected to a bottom surface of each of the first, second, and third recovery containers 2430a, 2430b, and 2430c. In one embodiment, first, second, and third recovery lines 2432a, 2432b, and 2432c respectively discharge fluids recovered into respective ones of the first, second, and third recovery containers 2430a, 2430b, and 2430c. The fluids may be supplied, for example, to an external fluid recycling system. The fluid recycling system may recycle the recovered fluids for reuse.

The elevation member 2440 includes a bracket 2441, an elevation shaft 2442, and an elevator 2443. The elevation member 2440 moves the recovery container 2430 in the third direction Z. The recovery container 2430 has a variable, relative height with respect to the spin head 2410. The inflow hole 2421 of any one recovery container 2430 is defined in a horizontal surface of the substrate S seated on the spin head 2410. The bracket 2441 is fixed to the recovery container 2430. The bracket 2441 has one end fixed and coupled to the elevation shaft 2442 moved in the third direction Z by the elevator 2443.

In one embodiment, a plurality of recovery containers 2430 may be provided. In this case, the bracket 2441 may be coupled to the outermost recovery container 2430. When the substrate S is loaded on the spin head 2410 or unloaded from the spin head 2410, the elevation member 2440 may move the recovery container 2430 downward to prevent the recovery container 2430 from interfering with the moving path of the transfer robot 2210, for transferring the substrate S.

When a fluid is supplied by the fluid supply part, and the spin head 2410 is rotated to perform the first process, the elevation member 2440 may move the recovery container 2430 in the third direction Z. The elevation member 2440 may move the recovery container 2430 to locate the inflow hole 2431 on the same horizontal plane as the substrate S, so that the fluid bouncing from the substrate S is recovered as a result of centrifugal force produced by rotation of the substrate S.

For example, in the case where the first process is performed in an order of the chemical process by a detergent, the cleaning process by a rinsing agent, and the first drying process by an organic solvent, the first, second, and third inflow holes 2431a, 2431b, and 2431c may move to the same horizontal plane as the substrate S. These inflow holes may move to recover the fluids into the first, second, and third recovery containers 2430a, 2430b, and 2430c, respectively, when the detergent, rinsing agent, and organic solvent are supplied. As described above, when the used fluids are recovered, environmental pollution may be prevented. Also, the fluids (which are expensive) may be recycled to reduce semiconductor manufacturing costs. In an alternative embodiment, the elevation member 2440 may move the spin head 2410 in the third direction Z, instead of moving the recovery container 2430.

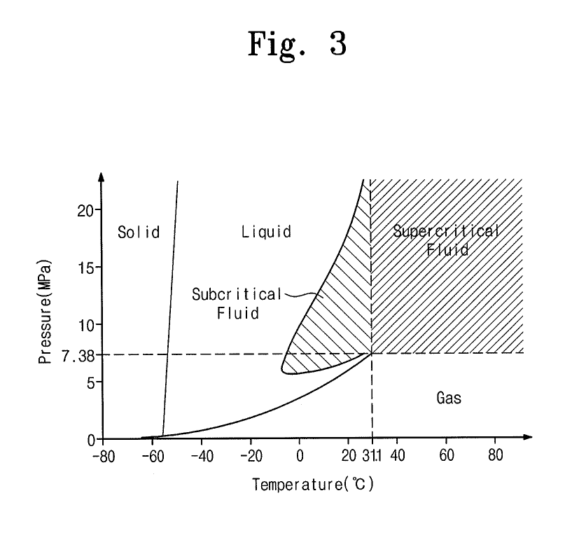

FIG. 3 is a graph of a phase change of carbon dioxide for a supercritical state. The supercritical state may represent a state where a material reaches a critical state that exceeds a critical temperature and a critical pressure. Thus, the material is not classified into liquid and gaseous states. The material in the supercritical state (hereinafter, referred to as a supercritical material) has a molecular density similar to that of liquid and viscosity similar to that of gas. Because the supercritical material has very high diffusion, penetration, and dissolution properties, the supercritical fluid has the advantage of a chemical reaction. Also, because the supercritical material does not exert interface tension on a fine structure due to a very low surface tension thereof, drying efficiency may be superior when the semiconductor device is dried, and pattern collapse may be prevented.

In one embodiment, a supercritical state of carbon dioxide (CO₂) may mainly be used as a fluid in the process for drying the substrate S. When carbon dioxide has a temperature of about 31.1° C. or more and a pressure of about 7.38 Mpa or more, the carbon dioxide may enter into the supercritical state. The carbon dioxide may have nonpoisonous, nonflammable, and inert properties. Also, the supercritical carbon dioxide may have a critical temperature and pressure less than those of other fluids. Thus, the supercritical carbon dioxide may be adjusted in temperature and pressure to easily control dissolution thereof.

Also, when compared to water or other solvents, supercritical carbon dioxide may have a diffusion coefficient less by about 10 times to about 100 times that of the water or other solvents, and a very low surface tension. Thus, the supercritical carbon dioxide may have physical properties suitable for performing the drying process. The carbon dioxide may be recycled from byproducts generated by various chemical reactions. In addition, the supercritical carbon dioxide used in the drying process may be circulated and reused to reduce environmental pollution.

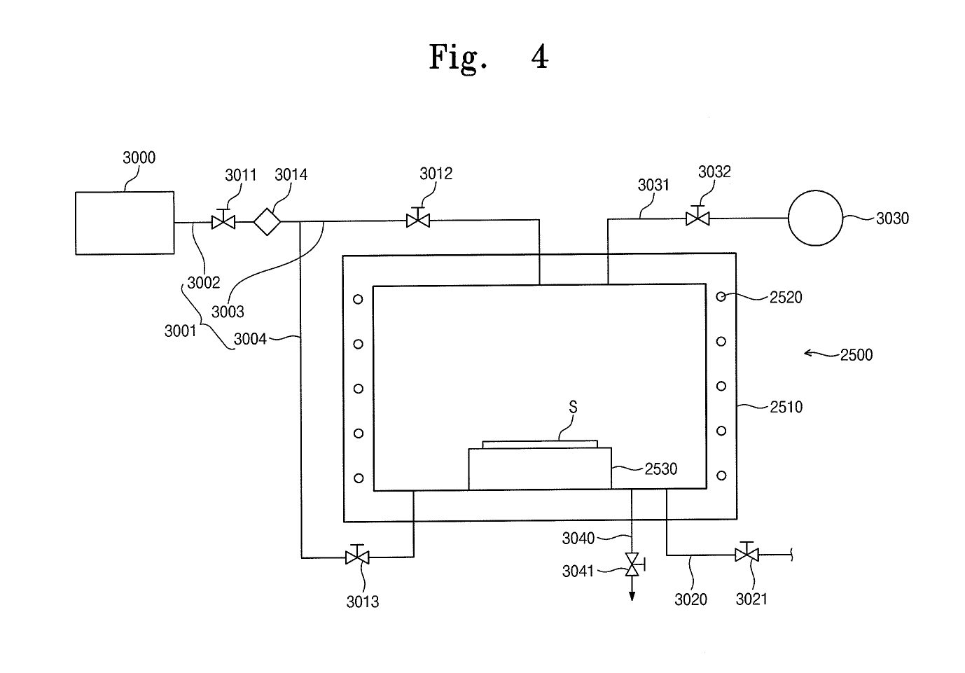

FIG. 4 illustrates an example of a tube of the second process chamber of FIG. 1. Referring to FIG. 4, the second process chamber 2500 includes a housing 2510, a heating member 2520, and a supporting member 2530. The second process is performed in the second process chamber 2500. The second process may be, for example, a second drying process for drying the substrate S using a supercritical fluid.

The housing 2510 may provide a space which is sealed from the outside to dry the substrate S therein. The housing 2510 may be formed of a material sufficient to endure high pressure. The heating member 2520 for heating the inside of the housing 2510 may be disposed between an inner wall and an outer wall of the housing 2510. In another embodiment, the heating member 2520 may be disposed at a position different from the above-described position.

The supporting member 2530 supports the substrate S and may be fixed and installed within the housing 2510. Alternatively, the supporting member 2530 may not be fixed, but may be rotatably disposed to rotate the substrate S seated on the supporting member 2530.

A supercritical fluid supply unit 3000 may convert the process fluid into a supercritical fluid. For example, the supercritical fluid supply unit 3000 may apply a temperature greater than a critical temperature and a pressure greater than a critical pressure to carbon dioxide, to convert the carbon dioxide into a supercritical fluid. The supercritical fluid generated in the supercritical fluid supply unit 300 is supplied into the housing 2510 through a supply tube 3001.

The supply tube 3001 includes a main tube 3002, an upper supply tube 3003, and a lower supply tube 3004. The main tube 3002 has one end connected to the supercritical fluid supply unit 3000. A branch portion 3005 from which the upper supply tube 3003 and the lower supply tube 3004 are branched is disposed on the other end of the main tube 3002. The upper supply tube 3003 has one end connected to the branch portion 3005 and the other end connected to an upper portion of the housing 2510. The lower supply tube 3004 has one end connected to the branch portion 3005 and the other end connected to a lower portion of the housing 2510.

Supply valves 3011, 3012, and 3013 are provided in the supply tube 3001. The main valve 3011 is disposed in the main tube 3002. The main valve 3011 may adjust an opening or closing of the main tube 3002 and an amount of process fluid flowing into the main tube 3002. The upper valve 3012 and the lower valve 3013 may be disposed in the upper supply tube 3003 and the lower supply tube 3004, respectively. The upper and lower valves 3012 and 3013 may adjust opening or closing of respective ones of the upper and lower supply tubes 3003 and 3004, and amounts of supercritical fluid of respective ones of the upper and lower supply tubes 3003 and 3004. A filter 3014 may be disposed between the branch portion 3005 and the main valve 3011. The filter 3014 filters foreign substances from the process fluid flowing into the supply tube 3001.

According to another embodiment, the upper supply tube 3003 or the lower supply tube 3004 may be omitted. Also, the supply tube 3001 may have one end connected to the process fluid supply unit 3000 and the other end connected to a side surface of the housing 2510.

A discharge tube 3020 discharges the process fluid and gas within the housing 2510 to the outside location. A discharge valve 3021 is disposed in the discharge tube 3020, for opening and closing the discharge tube 3020. Also, the discharge valve 3021 may adjust a flow rate of process fluid flowing into the discharge tube 3020.

A gas supply source 3030 is connected to the housing 2510 through gas supply tube 3031. A valve 3032 is disposed in the gas supply tube 3031, for opening and closing the gas supply tube 3031. Also, the valve 3032 may adjust a flow rate of inert gas supplied into the housing 2510. The gas supply tube 3031 may supply an inert gas into the housing 2510. The gas supply source 3030 may be a tank for storing the inert gas. The inert gas may include at least one of nitrogen (N₂), helium (He), neon (Ne), or argon (Ar). The inert gas may be supplied before the process fluid is supplied into the housing 2510. The inert gas supplied into the housing 2510 may increase an internal pressure of the housing 2510. For example, the inert gas may be supplied so that the internal pressure of the housing 2510 reaches a critical pressure or greater.

An exhaust tube 3040 may be connected to the housing 2510. The inert gas may be exhausted through the exhaust tube 3040. An exhaust valve 3041 is disposed in the exhaust tube 3040 for opening and closing the exhaust tube 3040. The exhaust valve 3041 may also adjust a flow rate of inert gas discharged into the exhaust tube 3040. The process fluid is supplied into the housing 2510 in a state where the internal pressure of the housing 2510 is increased by the inert gas.

Simultaneously, the inert gas within the housing 2510 is exhausted into the exhaust tube 3040. An amount of inert gas exhausted into the exhaust tube 3040 may correspond to that of the supercritical fluid supplied into the supply tube 3001. Thus, the internal pressure of the housing 2510 may be maintained at the critical pressure or greater. When supply of the supercritical fluid and exhaust of the inert gas are continuous for a certain time, the inside of the housing 2510 may be filled with the supercritical fluid.

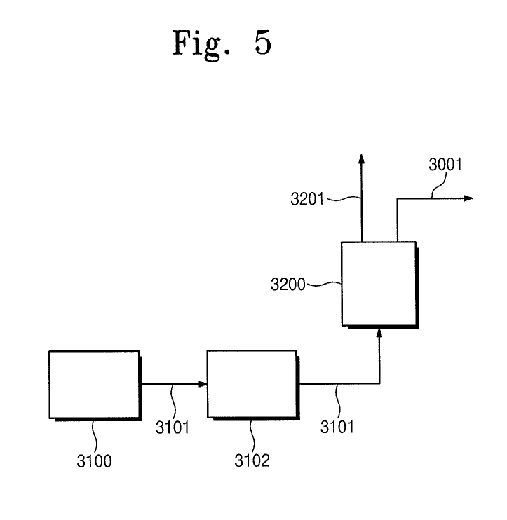

FIG. 5 illustrates an example of the process fluid supply unit 3000 illustrated in FIG. 4. Referring to FIG. 5, the process fluid supply unit 3000 may include a storing tank 3100 and a conversion tank 3200. The storing tank 3100 stores the process fluid, and the process fluid may be supplied into the storing tank 3100 from an external location. For example, the storing tank 3100 may receive the process fluid through a separate tube. The storing tank 3100 may store the process fluid in a liquid or gas state. Also, the inside of the storing tank 3100 may be maintained at a predetermined pressure or greater, to increase an amount of process fluid stored in the liquid state and to thereby increase the total amount of process fluid stored therein.

The conversion tank 3200 may store the process fluid at a preset temperature and pressure. The preset temperature may be close to critical temperature, and the preset pressure may be close to critical pressure. Thus, the process fluid may be stored in the conversion tank 3200 in a state close to supercritical state. The conversion tank 3200 may be connected to the storing tank 3100 through a connection tube 3101. The process fluid stored in the storing tank 3100 is supplied into the conversion tank 3200 through the connection tube 3101. The connection tube 3101 may be selectively opened and closed.

Also, the connection tube 3101 may be provided to control an amount of process fluid supplied from the storing tank 3100 to the conversion tank 3200. For example, a valve, a flow meter, or another flow regulator, may be provided in the connection tube 3101. The process fluid, converted into supercritical process fluid in the conversion tank, 3200 may be supplied into the second process chamber 2500 through the supply tube 3001.

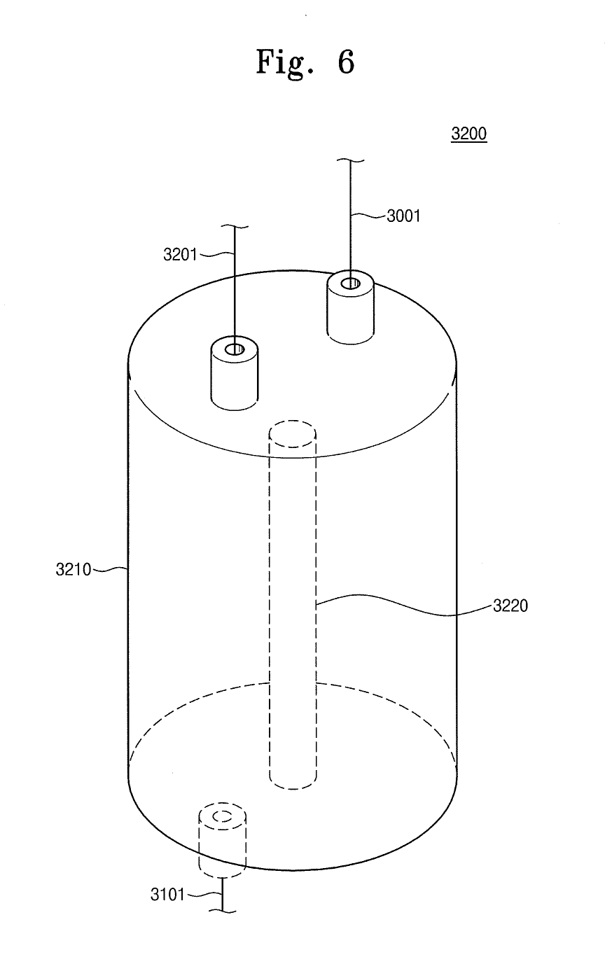

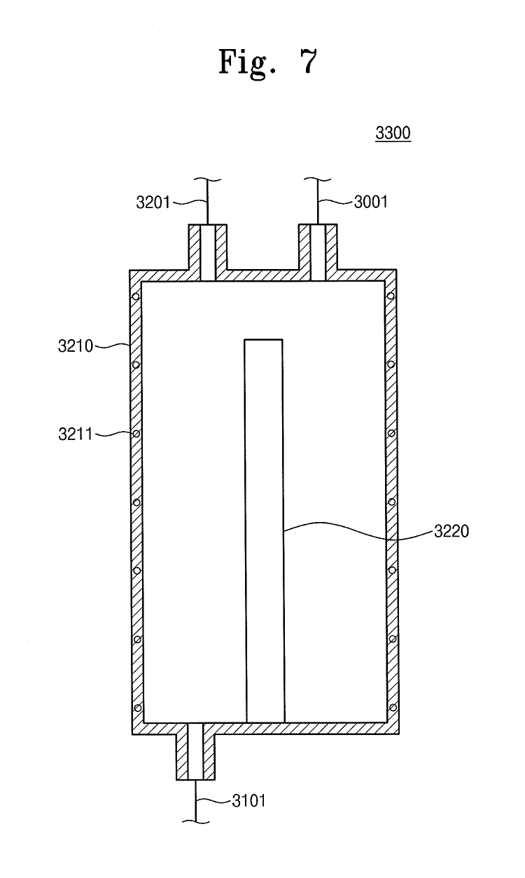

FIG. 6 illustrates an example of the conversion tank 3200 of FIG. 5, and FIG. 7 illustrates a cross-sectional view of the conversion tank of FIG. 6. Referring to FIGS. 5 to 7, the conversion tank 3200 includes a housing 3210 and a heater 3220.

The housing 3210 provides an inner space in which the process fluid is stored. The housing 3210 may have a shape which demonstrates durability against a pressure change of the inner space. For example, the housing 3210 may have a cylindrical or globular shape.

Each of the connection tube 3101 and the supply tube 3001 is connected to the housing 3210. The connection and supply tubes 3101 and 3001 may be connected to the housing 3210, in consideration of the flow of process fluid in the inner space of the housing 3210. For example, the connection and supply tubes 3101 and 3001 may be connected to the housing 3210 to face each other.

The housing 3210 may have a length which extends in a direction in which the connection tube 3101 faces the supply tube 3001. The connection tube 3101 may be connected to an upper portion of the housing 3210. Thus, the supercritical process fluid having low density may readily flow into the connection tube 3101 within the inner space. Also, the housing 3210 may include a heat member 3211, which may be buried in the housing 3210. Also, the heat member 3211 may be attached to an inner or outer wall of housing 3210 and may heat the process fluid in the inner space. In an alternative embodiment, the heat member 3211 may be omitted.

At least one heater 3220 may be fixed to the inner wall of the housing 3210. The heater 3220 may heat the process fluid accommodated in the housing 3210 until the process fluid reaches a critical temperature. For example, the heater 3220 may be fixed to the top or bottom surface of the inner wall of the housing 3210. The heater 3220 may be provided to cross the inner space. Thus, a contact area between the process fluid and the heater 3220 may be increased to improve heat exchange efficiency.

The heater 3220 may have a length in a direction in which the connection tube 3101 faces the supply tube 3001. Thus, when the process fluid flows from the supply tube 3001 to the connection tube 3101, the heater 3220 does not disturb the flow of the process fluid. Also, a contact time and area between the flowing process fluid the heater 3220 may be maximized. The process fluid may be expanded while being heated by the heater 3220 to increase the pressure thereof.

A pump 3102 may be disposed on the connection tube 3101 and may increase the pressure of the inner space of the conversion tank 3200. The pressure of the inner space of the conversion tank 3200 may not reach the critical pressure, due to expansion of the process fluid by the heating the heater 3220. Thus, the pump 3102 may increase the pressure of the inner space of the conversion tank 3200, to thereby increase pressure of the inner space to the critical pressure.

A vent tube 3201 discharges the process fluid within the inner space. The vent tube 3201 may be selectively opened and closed. Also, the vent tube 3201 may be adjusted in terms of opening degree to adjust the amount of process fluid discharged through the vent tube 3201.

The inner space of the conversion tank 3200 may be increased to a pressure greater than a preset value during operation. The pressure exceeding the preset value may generate stress on housing 3210 to reduce stability. In this case, the vent tube 3201 may serve to discharge the process fluid of the inner space to decrease the pressure of the inner space. Also, the vent tube 3201 may be used to discharge the process fluid of the inner space, so as to maintain or repair the conversion tank 3200.

If the temperature of the process fluid supplied into the second process chamber 2500 is not maintained within a predetermined range, particles in the second process chamber 2500 may be increasingly generated. According to one embodiment, even when the amount of process fluid supplied into the second process chamber 2500 increases, the process fluid may be heated to a target temperature for a short time. Thus, particle generation due to temperature deviation of the process fluid may be prevented. In an alternative embodiment, the vent tube 3201 may be omitted.

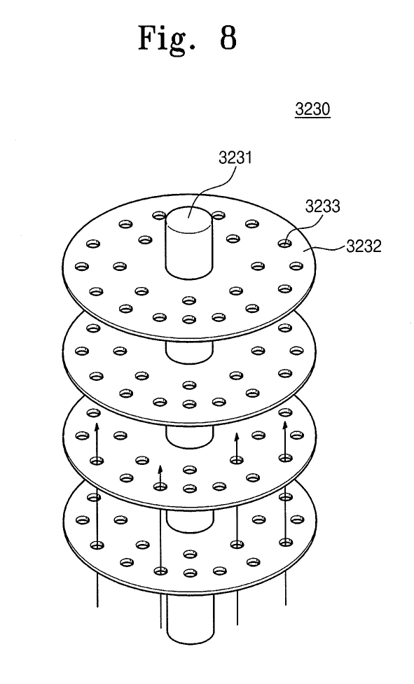

FIG. 8 illustrates a heater 3230 according to another embodiment. Referring to FIG. 8, the heater 3230 may be fixed to an inner wall of a housing 3210 and may have the same arrangement as heater 3220 of FIG. 7.

The heater 3230 includes a body 3231 and a heat exchange member 3232. The body 3231 may have a load shape, e.g., a cylindrical or prismatic shape. The body 3231 is fixed to the inner wall of the housing 3210.

At least one heat exchange member 3232 is fixed to an outer surface of the body 3231. The heat exchange member 3232 may have a plate shape. The heat exchange member 3232 may be disposed perpendicularly to a longitudinal direction of the body 3231. According to one embodiment, a plurality of heat exchange members 3232 may be provided. In this case, the heat exchange members 3232 may be disposed to be spaced apart from each other along the longitudinal direction of the body 3231.

The heat exchange member 3232 may have an outer shape corresponding to an inner shape thereof. Also, the heat exchange member 3232 may have an area less than that of the inner space, defined perpendicularly to the longitudinal direction of the body 3231. Thus, if the heater 3230 is disposed in the inner space, the heat exchange member 3232 is disposed spaced at a predetermined distance from the inner wall of the housing 3210. Accordingly, the heater 3230 may be increased in contact area with the process fluid through the heat exchange member 3232, to improve heat exchange efficiency.

The heat exchange member 3232 may have at least one hole 3233. The hole 3233 may provide a path through which the process fluid flows to improve fluidity of the process fluid. The heat exchange member 3232 may be formed of a metal having high thermal conductivity. Also, the heat exchange member 3232 may be formed of a metal having high corrosion resistance with respect to the process fluid. In an alternative embodiment, hole 3233 may be omitted.

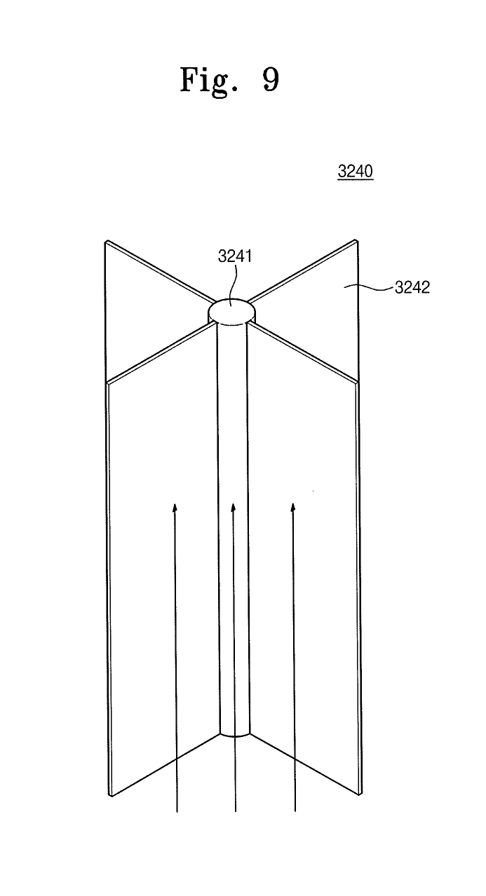

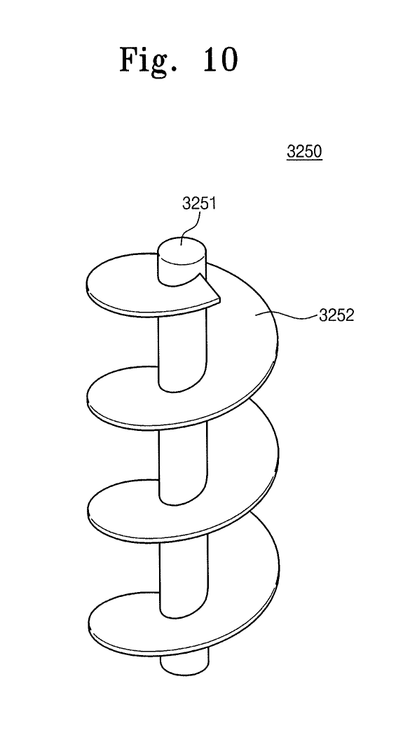

FIGS. 9 and 10 illustrate a heater according to another embodiment. As illustrated in FIG. 9, a heat exchange member 3242 may have a plate shape. At least one heat exchange member 3242 may be disposed on an outer surface of the body 3241, so that a longitudinal direction thereof is parallel to that of the body 3241. The plate may have a longitudinal direction parallel to a flowing direction of a process fluid. Accordingly, a heat-exchange area between the heater 3240 and the process fluid may be increased to improve fluidity of the process fluid. Bodies 3241 and 3251 may be the same as for heater 3230 of FIG. 8.

Referring to FIG. 10, a heat exchange member 3235 may be spirally disposed on an outer surface of the body 3251. The process fluid may flow in a spiral shape along the heat exchange member 3235. Accordingly, a heat-exchange area between the heater 3250 and the process fluid may be increased to improve fluidity of the process fluid.

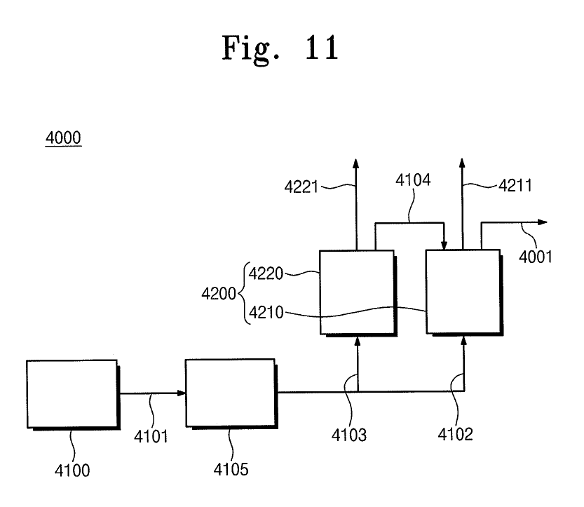

FIG. 11 illustrates a process fluid supply unit 4000 according to another embodiment. Referring to FIG. 11, a process fluid supply unit 4000 includes a storing tank 4100, a pump 4102, and a conversion tank 4200. A storing tank 4100 and a pump 4105 provided in a connection tube 4101 may be the same as the storing tank and pump 3101 of the process fluid supply unit 3000 of FIG. 5.

The conversion tank 4200 includes a first conversion tank 4210 and a second conversion tank 4220. The first and second conversion tanks 4210 and 4220 are connected parallel to the connection tube 4101. The connection tube 4101 may have an end that is branched into a first branch tube 4102 and a second branch tube 4103 and respectively connected to the first and second conversion tanks 4210 and 4220. Each of the first and second branch tubes 4102 and 4103 is may be individually opened and closed. Each of the first and second branch tubes 4102 and 4103 may be adjusted in terms of its opening degree to adjust an amount of processing fluid.

The first conversion tank 4210 is connected to the second process chamber 2500 through a supply tube 4001. The second conversion tank 4220 is connected to the first conversion tank 4210 through a supplement tube 4104. The first and second conversion tanks 4210 and 4220 may include a first vent tube 4211 and a second vent tube 4221, respectively. In an alternative embodiment, the first and second tanks 4210 and 4220 may be omitted. Also, each of the first and second vent tubes 4211 and 4221 may perform the same function as vent tube 3210 in conversion tank 3200 of FIGS. 5 to 7.

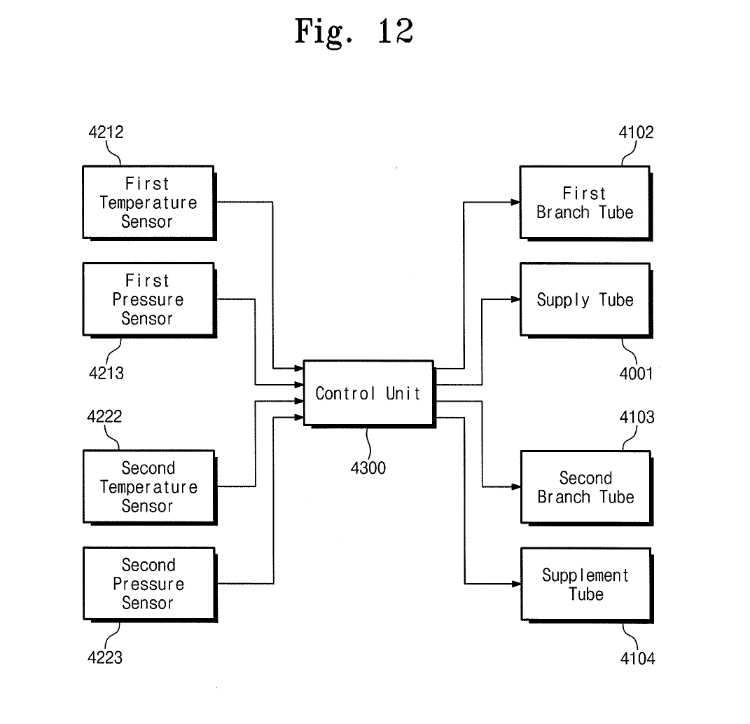

FIG. 12 illustrates a state in which the process fluid supply unit of FIG. 11 is controlled. Referring to FIGS. 11 and 12, the first conversion tank 4210 includes a first temperature sensor 4212 and a first pressure sensor 4213. The second conversion tank 4220 includes a second temperature sensor 4222 and a second pressure sensor 4223. The first temperature sensor 4212 and first pressure sensor 4213 detect a temperature and pressure of an inner space of the first conversion tank 4210. The second temperature sensor 4222 and second pressure sensor 4223 detect a temperature and pressure of an inner space of the second conversion tank 4220.

Data detected in the temperature sensors 4212 and 4222 and the pressure sensors 4213 and 4223 is transmitted to a control unit 4300. The control unit 4300 adjusts an opening and closing degree of each of the first branch tube 4102, the supply tube 4001, the second branch tube 4103, and the supplement tube 4104. An operational process of the process fluid supply unit 4000 will now be described.

The first and second conversion tanks 4210 and 4220 store the process fluid in a state where the pressure and the temperature of the inner space thereof are close to the critical pressure and temperature of the process fluid. Each time when a substrate is successively processed in the second process chamber 2500, the control unit 4300 opens the supply tube 4001 to supply the process fluid from the first conversion tank 4210 to the second process chamber 2500. Also, the control unit opens the first branch tube 4102 to supply the process fluid in an amount corresponding to that of the process fluid discharged from the first conversion tank 4210. The control unit 4300 may open the first branch tube 4102 in a state where the supply tube 4001 is closed when the supply of the process fluid into the second process chamber 2500 is finished.

Also, the control unit 4300 may open the supply tube 4001 and the first branch tube 4101 at the same time. It takes a predetermined time to heat the process fluid newly supplied into the first conversion tank 4210. Also, an amount of process fluid in the first conversion tank 4210 may decrease based on supply of the process fluid into the second process chamber 2500. Thus, the temperature or pressure of the inner space of the first conversion tank 4210 may lowered below a preset temperature or pressure while the process fluid is supplied from the first conversion tank 4210 to the second process chamber 2500. As a result, if the process fluid is supplied into the second process chamber 2500 in the state where the temperature or pressure of the inner space are below the preset temperature or pressure, the process decreases in uniformity, thereby increasing particles generated inside the second process chamber 2500.

When the data transmitted from the first temperatures sensor 4212 or the first pressure sensor 4213 is below the preset temperature or pressure, the control unit 4300 opens the supplement tube 4101 to supply the process fluid stored in the second conversion tank 4220 into the first conversion tank 4210. Here, the control unit 4300 may close the first branch tube 4102 or adjust an opening degree of the first branch tube 4102, to reduce an amount of process fluid supplied into the first branch tube 4102. The temperature or pressure of the inner space of the first conversion tank 4210 may be recovered above the preset temperature or pressure according to supply of the process fluid from the second conversion tank 4220 to the supplement tube 4104.

The control unit 4300 opens the second branch tube 4103 to supplement the process fluid in the second conversion tank 4220. The amount of process fluid supplemented into the second conversion tank 4220 may be the same as the amount of process fluid supplied to the first conversion tank 4210 through the supplement tube 4104. The second branch tube 4103 may be opened while the process fluid is supplied from the second conversion tank 4220 to the first conversion tank 4210. Alternatively, the second branch tube 4103 may be opened after supply of the process fluid from the second conversion tank 4220 to the first conversion tank 4210 is finished.

Carbon dioxide heated and pressurized in the second conversion tank 4220 is supplied into the first conversion tank 4210. Thus, an operation time of the pump 4105 may be prevented from being excessive and an output of the pump 4105 from being significantly increased, so as to increase the pressure of the first conversion tank 4210. As a result, the useful lifetime of the pump 4105 may be increased.

Also, the pump 4105 may pressurize the inner space of the second conversion tank 4220, in a state where the pressure of the inner space of the first conversion tank 4210 is stable. Thus, pump 4105 may pressurize the first and second conversion tanks 4210 and 4220 at the same time, to prevent output of pump 4105 from being increased.

Also, according to one embodiment, when the temperature or pressure of the inner space of the first conversion tank 4210 are lowered below the preset temperature or pressure, the control unit may rapidly recover the temperature or pressure above the preset temperature and pressure.

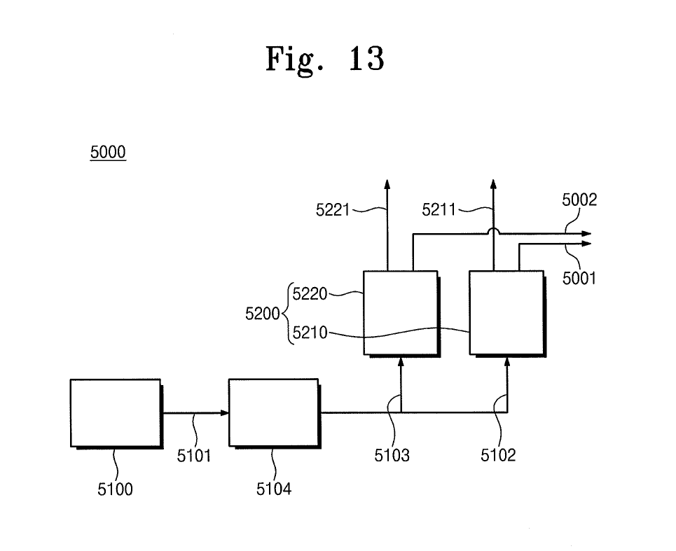

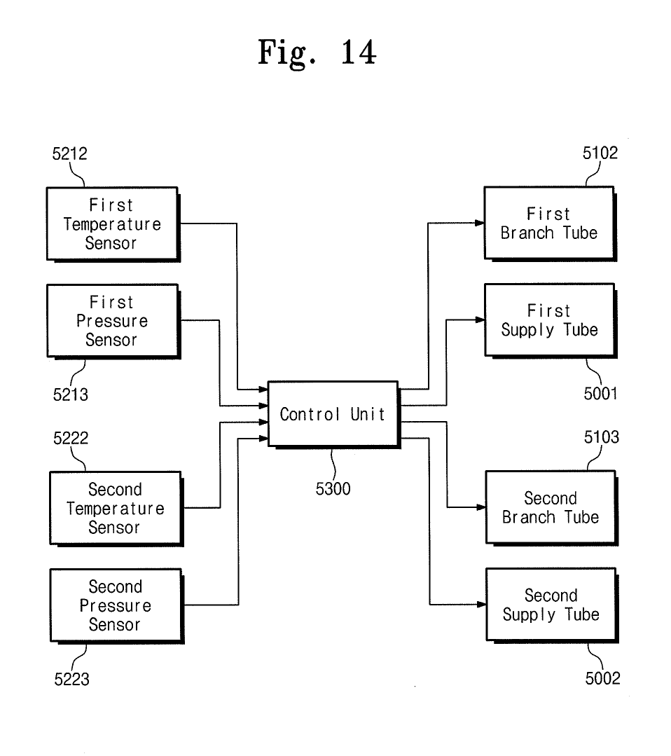

FIG. 13 illustrates a process fluid supply unit 5000 according to another embodiment, and FIG. 14 illustrates a state in which the process fluid supply unit 5000 of FIG. 13 is controlled.

Referring to FIGS. 13 and 14, a process fluid supply unit 5000 includes a storing tank 5100, a pump 5104, and a conversion tank 5200. The storing tank 5100 and the pump 5104 provided in a connection tube 5101 may be the same as the storing tank 3100 and the pump 3102 of the process fluid supply unit 3000 of FIG. 5.

The conversion tank 5200 includes a first conversion tank 5210 and a second conversion tank 5220. The first and second conversion tanks 5210 and 5220 are connected in parallel to each other. More specifically, the connection tube 5101 may have an end that is branched into a first branch tube 5102 and a second branch tube 5103, and respectively connected to the first and second conversion tanks 5210 and 5220. The first conversion tank 5210 is connected to the second process chamber 2500 through the first supply tube 5001. The second conversion tank 5220 is connected to the second process chamber 2500 through the second supply tube 5002.

The first conversion tank 5210 includes a first temperature sensor 5212 and a first pressure sensor 5213. The second conversion tank 5220 includes a second temperature sensor 5222 and a second pressure sensor 5223. The first temperature sensor 5212 and the first pressure sensor 5213 detect a temperature and a pressure of an inner space of the first conversion tank 5210. The second temperature sensor 5222 and the second pressure sensor 5223 detect a temperature and a pressure of an inner space of the second conversion tank 5220.

The control unit 5300 may control a degree of opening and closing of the first branch tube 5102, the first supply tube 5001, the second branch 5103, and the second supply tube 5002, with reference to data transmitted from the temperature sensors 5212 and 5222, or transmitted from the pressure sensors 5213 and 5223. An operational process of the process fluid supply unit 5000 will now be described.

The process fluid stored in the first conversion tank 5210 or the second conversion tank 5220 may be selectively supplied into the second process chamber 2500. More specifically, a temperature or pressure of the inner space of the conversion tank 5200 may decrease below a preset pressure or temperature while the process fluid is supplied as described above. Thus, the control unit 5300 may supply the process fluid from the conversion tank 5200, in which the temperature and pressure of the inner space thereof is maintained in a range of a preset pressure and a preset temperature to the second process chamber 2500.

Also, if the temperature or pressure of the inner space of the first and second conversion tanks 5210 and 5220 is maintained in a range of a preset temperature and pressure, the process fluid may be selectively supplied from the conversion tanks 5200 into the second process chamber 2500. For example, the control unit 5300 may open the first supply tube 5001 to supply the process fluid from the first conversion tank 5210 and may close the second supply tube 5002. If an amount of process fluid stored in the first conversion tank 5210 decreases due to repeated processes, the control unit 5300 supplies the process fluid from the second conversion tank 5220 to the second process chamber 2500. Also, the control unit 5300 may open the first branch tube 4102 to refill the process fluid in the inner space of the first conversion tank 5210, while the process fluid is supplied from second conversion tank 5220 to second process chamber 2500.

If the temperature or pressure of the inner space of the first and second conversion tanks 5210 and 5220 is maintained in a range of a preset temperature and pressure, the process fluid may be simultaneously supplied from the first and second tanks 5210 and 5220 into the second process chamber 2500. The control unit 5300 may separately adjust the amounts of the process fluid supplied from the first and second conversion tank 5210 and 5220, respectively.

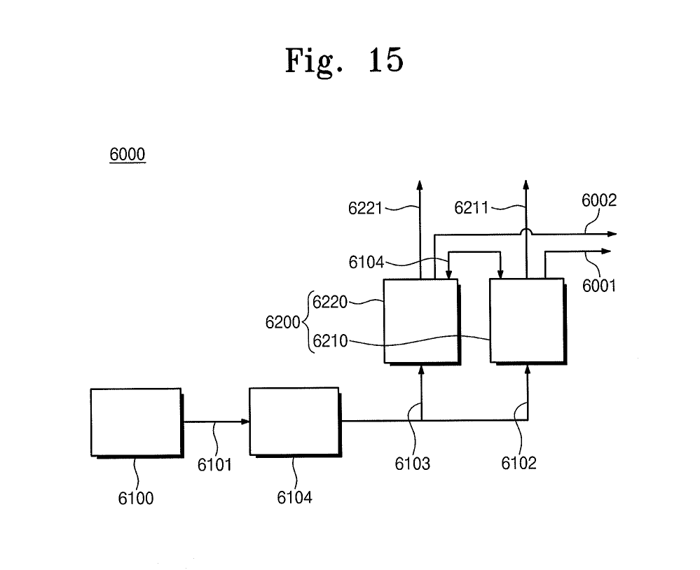

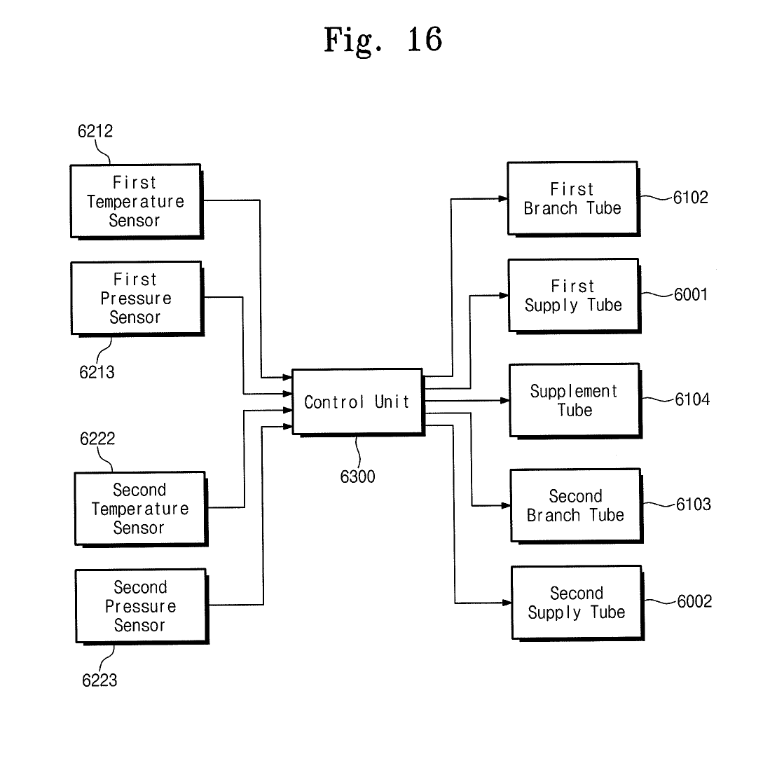

FIG. 15 illustrates a process fluid supply unit 6000 according to another embodiment, and FIG. 16 illustrates a state in which this process fluid supply unit is controlled.

Referring to FIGS. 15 and 16, process fluid supply unit 6000 includes a storing tank 6100, a pump 6104, and a conversion tank 6200. The storing tank 6100 and the pump 6104 may be the same as that of the process fluid supply unit 5000 of FIG. 13.

The conversion tank 6200 includes a first conversion tank 6210 and a second conversion tank 6220. The first and second conversion tanks 6210 and 6220 are connected in parallel to each other. More specifically, a connection tube 6101 may have an end branched into a first branch tube 6102 and a second branch tube 6103 to connect the end to the first and second conversion tanks 6210 and 6220, respectively.

The first conversion tank 6210 is connected to the second process chamber 2500 through a first supply tube 6001. The second conversion tank 6220 is connected to the second process chamber 2500 (see FIG. 2) through a second supply tube 6002. The first and second conversion tanks 6210 and 6220 are connected to each other through a supplement tube 6104. The supplement tube 6104 is provided so that a process fluid flows from the first conversion tank 6210 to the second conversion tank 6220, or from the second conversion tank 6220 to the first conversion tank 6210.

The first conversion tank 6210 includes a first temperature sensor 6212 and a first pressure sensor 6213. The second conversion tank 6220 includes a second temperature sensor 6222 and a second pressure sensor 6223.

The control unit 6300 may control a degree of opening and closing of the first branch tube 6102, the first supply tube 6001, the second branch tube 6103, the second supply tube 6002, and the supplement tube 6104 with reference to data transmitted from the temperature sensors 6212 and 6222 or transmitted from the pressure sensors 6213 and 6223. An operational process of the process fluid supply unit 6000 will now be described.

The process fluid supply unit 6000 may be operated in two modes. In a first mode, the process fluid supply unit 600 may be operated similar to the operation method of the process fluid supply unit 4000 of FIG. 11. More specifically, one of the first or second conversion tanks 6210 and 6220 may function as a main conversion tank and the other one may function as a sub-conversion tank. The main conversion tank is operated to correspond to a function of first conversion tank 4210 of FIG. 11. The sub-conversion tank is operated to correspond to second conversion tank 4220 of FIG. 11.

When a pressure or temperature of an inner space of the main conversion tank is lowered below a preset temperature or pressure, the process fluid may be supplied from the sub-conversion tank into the main conversion tank through supplement tube 6104. In the first mode, a method of controlling one of the first or second supply tube 6001 or 6002, the first branch tube 6102, the supplement tube 6104, and the second branch tube 6103 using the control unit 6300 may be performed in the same manner as control unit 4300 of FIG. 12.

In a second mode, the process fluid supply unit 6000 is operated in a manner similar to the operation method of the process fluid supply unit 5000 of FIG. 13. The supplement tube 6104 is controlled to be closed in the second mode. More specifically, a temperature or pressure of the inner space of the conversion tank 6200 may be lowered below the preset pressure or temperature while the process fluid is supplied.

Thus, the control unit 6300 may supply the process fluid from the conversion tank 6200, in which the temperature and pressure of the inner space are maintained in ranges of the preset pressure and temperature, to the second process chamber 2500. In the second mode, a method of controlling the first branch tube 6102, the first supply tube 6001, the second branch tube 6103, and the second supply 6002 using the control unit 6300 is the same as the method performed by control unit 5300 of FIG. 14.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate treating apparatus, comprising:
a chamber to dry a substrate using a fluid in a supercritical state; and
a process fluid supply unit to supply the fluid to the chamber, wherein the process fluid supply unit includes:
a storing tank to store the fluid; and
a conversion tank connected to the storing tank through a connection tube and connected to the chamber through a supply tube, the conversion tank including a heater to heat the fluid.

2. The apparatus as claimed in claim 1, wherein the heater comprises:
a body coupled to an inner wall of a housing of the conversion tank; and
at least one heat exchange member coupled to an outer surface of the body.

3. The apparatus as claimed in claim 2, wherein:
the at least one heat exchange member has a plate shape, and
the at least one heat exchange member is disposed to cross a longitudinal direction of the body.

4. The apparatus as claimed in claim 3, further comprising:
a plurality of heat exchange members arranged to be spaced apart from each other along the longitudinal direction of the body.

5. The apparatus as claimed in claim 3, wherein the at least one exchange member has a hole.

6. The apparatus as claimed in claim 2, wherein:
the at least one heat exchange member has a plate shape, and
the at least one heat exchange member is on the body and is substantially parallel to a longitudinal direction of the body.

7. The apparatus as claimed in claim 2, wherein the at least one heat exchange member is spirally disposed on the outer surface of the body.

8. The apparatus as claimed in claim 1, wherein:
the conversion tank includes a housing including the inner space, and
the connection tube and the supply tube are connected to the housing and face each other.

9. The apparatus as claimed in claim 8, wherein:
the heater extends in a longitudinal direction, and
the connection tube extends in the longitudinal direction and faces the supply tube.

10. The apparatus as claimed in claim 1, wherein the conversion tank includes:
a first conversion tank; and
a second conversion tank substantially parallel to the first conversion tank and connected to the connection tube.

11. The apparatus as claimed in claim 10, wherein:
the supply tube is connected to the first conversion tank, and
the second conversion tank is connected to the first conversion tank through a supplement tube to supply the fluid into the first conversion tank.

12. The apparatus as claimed in claim 10, wherein:
the first conversion tank is connected to the chamber through a first supply tube, and
the second conversion tank is connected to the chamber through a second supply tube.

13. The apparatus as claimed in claim 10, wherein:
the first conversion tank is connected to the chamber through a first supply tube,
the second conversion tank is connected to the chamber through a second supply tube, and
the first and second conversion tanks are connected to each other through a supplement tube.

14. The apparatus as claimed in claim 13, wherein:
one of the first or second conversion tank functions as a main conversion tank to supply the fluid into the chamber, and
the other of the first or second conversion tank functions as a sub-conversion tank to supply the fluid into the main conversion tank.

15. The apparatus as claimed in claim 13, wherein the first or second conversion tank selectively supplies the fluid into the chamber.

16. A substrate treating apparatus, comprising:
a surface to support a substrate; and
a chamber to dry the substrate using a fluid in a supercritical state, wherein the surface is included in the chamber.

17. The substrate as claimed in claim 16, further comprising:
a supply source to supply the fluid to the chamber,
wherein the supply source includes a first tank to store the fluid and a second tank to receive the fluid from the first tank and wherein the second tank includes a heater to heat the fluid.

18. The substrate as claimed in claim 17, wherein the fluid is heated and pressurized in at least one of the first tank or the second tank.

19. The substrate as claimed in claim 16, further comprising:
a circulator to recycle the fluid in the chamber after the substrate is dried.

20. The substrate as claimed in claim 16, wherein the fluid in the supercritical state includes carbon dioxide.
